(19) United States
(12) Patent Application Publication
(10) Pub. No.: US 2024/0011214 A1
(43) Pub. Date: Jan. 11, 2024

(54) OPERATION PANEL ASSEMBLY FOR ELECTRIC APPLIANCES AND WASHING MACHINE EMPLOYING SAME

(71) Applicant: SAMSUNG ELECTRONICS CO., LTD., Suwon-si (KR)

(72) Inventors: Hyunseop PARK, Suwon-si (KR); Jungyoon KIM, Suwon-si (KR); Junga PARK, Suwon-si (KR); Wungchul CHOI, Suwon-si (KR)

(21) Appl. No.: 18/452,564

(22) Filed: Aug. 21, 2023

Related U.S. Application Data
(63) Continuation of application No. PCT/KR2022/003004, filed on Mar. 3, 2022.

(30) Foreign Application Priority Data
Apr. 23, 2021 (KR) 10-2021-0053104

(51) Int. Cl. D06F 34/34; D06F 34/30; D06F 34/32; H05K 5/00

(52) U.S. Cl. CPC D06F 34/34; D06F 34/30; D06F 34/32; H05K 5/0018

(57) ABSTRACT

An operation panel assembly of the disclosure includes a first cover including a first front portion defining an opening and a first side portion extending from the first front portion, wherein the first front portion and the first side portion form a first accommodation space, an operation panel board including a first surface on which an electronic component aligned with the opening of the first cover is disposed, and a second surface opposite to the first surface and arranged in the first accommodation space so that the first surface faces the first front portion, and a second cover coupled to the first cover to close the first accommodation space.

### CROSS-REFERENCE TO RELATED APPLICATIONS

This application is a continuation application, under 35 U.S.C. § 111(a), of International Patent Application No. PCT/KR2022/003004, filed on Mar. 3, 2022, which claims priority to Korean Patent Application No. 10-2021-0013565, filed on Apr. 23, 2021, the content of which in its entirety is herein incorporated by reference.

### TECHNICAL FIELD

Embodiments of the disclosure relate to an operation panel assembly for an electric appliance, which is capable of protecting electronic components inside the operation panel assembly from water and moisture, and a washing machine employing the operation panel assembly.

### BACKGROUND ART

An electric appliance includes an operation panel assembly that receives a user's input for operating the electric appliance and displaying an operation of the electric appliance. Because the operation panel assembly is exposed to the outside of the electric appliance, the operation panel assembly may be directly exposed to external moisture and/or water depending on an environment in which the electric appliance is used. The operation panel assembly includes electronic components. The electronic components may include a manipulation unit for converting a user's manipulation into an electrical signal and a display for displaying an operation state of the electric appliance. In an embodiment, the manipulation unit may include a switch element, and the display may include various types of display elements capable of displaying information. The electronic components may include a circuit board with an electrical circuit including the manipulation unit and the display. When the electronic components are exposed to water and/or moisture, the exposure may damage the electronic components and cause the electric appliance to malfunction.

### SUMMARY

The disclosure provides an operation panel assembly capable of preventing intrusion of moisture.

The disclosure provides an operation panel assembly that is relatively simple to manufacture and is capable of preventing intrusion of moisture.

The disclosure provides a washing machine employing the operation panel assembly.

A washing machine in an embodiment of the disclosure includes: a body including a washing tub; and an operation panel assembly configured for at least one of manipulation input and display of an operation state of the body, and the operation panel assembly includes a first cover including a first front portion defining an opening and a first side portion extending from the first front portion, wherein the first front portion and the first side portion form a first accommodation space; an operation panel board including a first surface on which an electronic component aligned with the opening of the first cover is disposed and a second surface opposite to the first surface and arranged in the first accommodation space so that the first surface faces the first front portion; and a second cover coupled to the first cover to close the first accommodation space.

In an embodiment of the disclosure, the washing machine may include a waterproof coating layer formed on the first surface of the operation panel board. The waterproof coating layer may include a conformal coating layer.

In an embodiment of the disclosure, the washing machine may include a through-hole defined to penetrate the operation panel board; and a fusion protrusion extending from the first front portion, passing through the through-hole, protruding outward from the second surface of the operation panel board, and including a protruding end fused to the second surface.

In an embodiment, the second cover may include a second front portion facing the first front portion of the first cover and a second side portion extending from the second front portion to an opposite side of the first cover, and an opposite side of the second front portion may be open.

In an embodiment of the disclosure, the washing machine may include a main board arranged in a second accommodation space formed by the second front portion and the second side portion. The main board may be accommodated in the second accommodation space so that a component surface faces an opposite side of the second front portion.

In an embodiment of the disclosure, the washing machine may include a waterproof molding layer filling the second accommodation space so as to cover the component surface of the main board.

In an embodiment of the disclosure, the washing machine may include an operation panel disposed opposite to the first front portion of the first cover so that the electronic component may be accessed through the opening.

An operation panel assembly in an embodiment of the disclosure includes: a first cover including a first front portion defining an opening and a first side portion extending from the first front portion, wherein the first front portion and the first side portion form a first accommodation space; an operation panel board including a first surface on which an electronic component aligned with the opening of the first cover is disposed and a second surface opposite to the first surface and arranged in the first accommodation space so that the first surface faces the first front portion; and a second cover coupled to the first cover to close the first accommodation space.

In an embodiment of the disclosure, the operation panel assembly may include a waterproof coating layer formed on the first surface of the operation panel board. The waterproof coating layer may include a conformal coating layer.

In an embodiment of the disclosure, the operation panel assembly may include a through-hole defined to penetrate the operation panel board; and a fusion protrusion extending from the first front portion, passing through the through-hole, protruding outward from the second surface of the operation panel board, and including a protruding end fused to the second surface.

In an embodiment, the second cover may include a second front portion facing the first front portion of the first cover and a second side portion extending from the second front portion to an opposite side of the first cover, and an opposite side of the second front portion may be open. In an embodiment of the disclosure, the operation panel assembly may include a main board arranged in a second accommodation space formed by the second front portion and the second side portion. The main board may be accommodated in the second accommodation space so that a component surface faces an opposite side of the second front portion. In an embodiment of the disclosure, the operation panel assembly may include a waterproof molding layer filling the second accommodation space so as to cover the component surface of the main board.

In an embodiment of the disclosure, the operation panel assembly may include an operation panel disposed opposite to the first front portion of the first cover so that the electronic component may be accessed through the opening.

Because the component surface of the operation panel board is covered by the first front portion of the first cover, the component surface may be protected from moisture. A process of forming a polyurethane waterproof molding layer for protecting the operation panel board may be omitted, which may reduce the manufacturing cost of the operation panel assembly.

### DESCRIPTION OF DRAWINGS

FIG. 1 is an exploded perspective view of an embodiment of an operation panel assembly for an electric appliance, according to the disclosure.

FIG. 2 is a schematic cross-sectional view of an embodiment of the operation panel assembly for the electric appliance, taken along line A-A′ of FIG. 1, according to the disclosure.

FIG. 3 is a schematic cross-sectional view of an embodiment of the operation panel assembly for the electric appliance, taken along line B-B′ of FIG. 1, according to the disclosure.

FIG. 4 is a cross-sectional view of an embodiment of an operation panel assembly for an electric appliance, according to the disclosure.

FIG. 5 is a cross-sectional view of the operation panel assembly taken along line C-C′ of FIG. 1.

FIG. 6 is an exploded perspective view of an embodiment of an operation panel assembly for an electric appliance, according to the disclosure.

FIG. 7 is a schematic cross-sectional view of an embodiment of the operation panel assembly for the electronic appliance, taken along line D-D of FIG. 6, according to the disclosure.

FIG. 8 is a schematic cross-sectional view of an embodiment of the operation panel assembly for the electronic appliance, taken along line E-E′ of FIG. 6, according to the disclosure.

FIGS. 9 and 10 are schematic perspective views of an embodiment of an electric appliance according to the disclosure.

### DETAILED DESCRIPTION

The terms used in the specification are general terms currently widely used in the art based on functions described in the disclosure, but may be changed according to an intention of a technician engaged in the art, precedent cases, advent of new technologies, etc. Furthermore, some particular terms may be arbitrarily selected by the applicant, and in this case, the meaning of the selected terms will be described in detail in the detailed description of the disclosure. Thus, the terms used herein should be defined not by simple appellations thereof but based on the meaning of the terms together with the overall description of the disclosure. Throughout the specification, when a part “includes” or “comprises” an element, unless there is a particular description contrary thereto, it is understood that the part may further include other elements, not excluding the other elements.

Embodiments of the disclosure will be described more fully hereinafter with reference to the accompanying drawings so that they may be easily implemented by one of ordinary skill in the art. However, the disclosure may be implemented in different forms and should not be construed as being limited to the embodiments set forth herein. In addition, parts not related to descriptions of the disclosure are omitted to clearly explain the disclosure in the drawings, and like reference numerals denote like elements throughout. Hereinafter, embodiments of the disclosure will be described with reference to the accompanying drawings.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

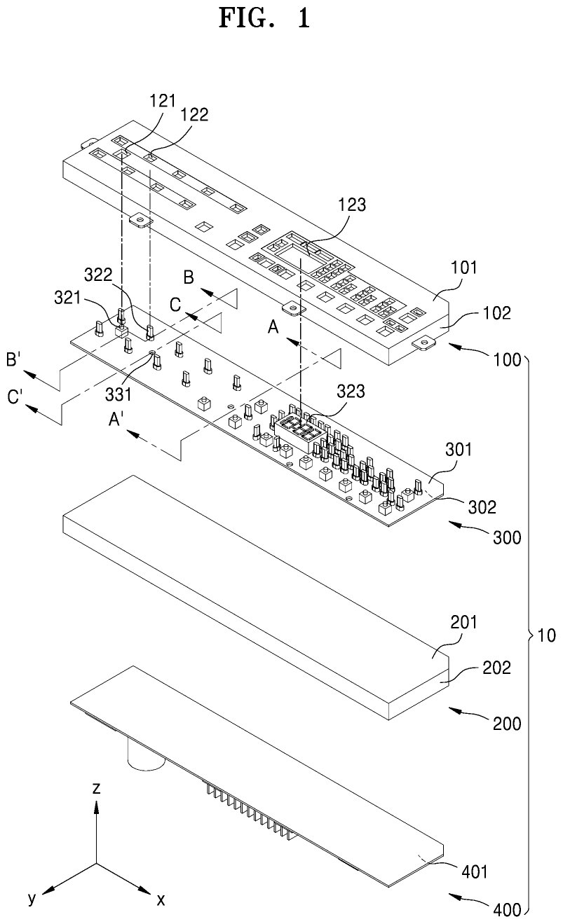

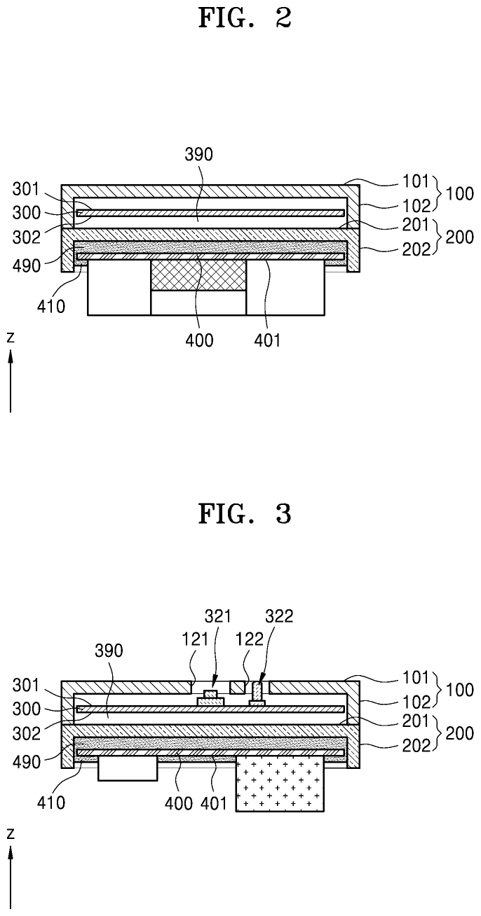

FIG. 1 is an exploded perspective view of an embodiment of an operation panel assembly for an electric appliance, according to the disclosure. FIG. 2 is a schematic cross-sectional view of an embodiment of the operation panel assembly for the electric appliance, taken along line A-A′ of FIG. 1, according to the disclosure. In FIG. 2, an opening of a first cover 100, electronic components on an operation panel board 300, etc. are omitted. FIG. 3 is a schematic cross-sectional view of an embodiment of the operation panel assembly for the electric appliance, taken along line B-B′ of FIG. 1, according to the disclosure. Referring to FIGS. 1, 2, and 3, an operation panel assembly for an electric appliance, according to the disclosure, may include the first cover 100, the operation panel board 300, and a second cover 200.

The first cover 100 may include a first front portion 101 defining at least one opening and a first side portion 102 extending from the first front portion 101. The first cover 100 may be shaped to define an open rear space that is the opposite side of the first front portion 101. The first front portion 101 and the first side portion 102 define a first accommodation space 390 for accommodating the operation panel board 300. In an embodiment, the first side portion 102 may extend from edges of the first front portion 101 in a thickness direction (e.g., z direction in FIGS. 1 to 3), for example. The thickness direction may be a normal direction to a plane defined by an x direction and a y direction perpendicular to the x direction. The first front portion 101 may have a flat shape, or may have a partially or fully curved shape.

The at least one opening may include a first opening 121 for receiving a manipulation input from a user. The at least one opening may include second openings 122 and 123 for displaying an operation state of the electric appliance. The first opening 121 may be an opening for a switch element, a dial element, etc. In an embodiment, the second opening 122 may be an opening for a blinking display element such as a light-emitting diode (LED), and the second opening 123 may be an opening for a display element such as a seven segment display element, for example.

The operation panel board 300 may include a first surface 301 on which at least one electronic component aligned with the opening of the first cover 100 is disposed (e.g., mounted), and a second surface 302 opposite to the first surface 301. The operation panel board 300 is accommodated in the first accommodation space 390. The operation panel board 300 is arranged inside the first cover 100. The operation panel board 300 is arranged inside the first cover 100, i.e., in the first accommodation space 390 so that the first surface 301 faces the first front portion 101 in the thickness direction. The operation panel board 300 may be coupled to the first cover 100 by a screw fastening method, for example. The operation panel board 300 may be a printed circuit board (PCB), for example. In an embodiment, the operation panel board 300 may be a single-sided PCB having a circuit pattern printed on the first surface 301, for example.

The electronic component is disposed (e.g., mounted) on the first surface 301 of the operation panel board 300. The electronic component may include a manipulation element 321 for receiving a manipulation input from the user. The manipulation element 321 may include, e.g., a switch element operated due to a pressing pressure, static electricity, or the like, a dial element operated due to rotary manipulation, etc. In the illustrated embodiment, the manipulation element 321 is a tact switch operated by a pressing pressure. When the operation panel board 300 is coupled to the first cover 100, the manipulation element 321 is aligned with the first opening 121 of the first cover 100, as shown in FIG. 3. The user may operate the manipulation element 321 via the first opening 121 by pressing a manipulation part (521 of FIG. 6) on an operation panel (500 of FIG. 6) as described below.

The electronic component may include display elements 322 and 323 for displaying an operation state of the electric appliance. The display elements 322 and 323 are respectively aligned with the second openings 122 and 123 of the first cover 100. The display element 322 may be a blinking display element such as an LED, for example. When the operation panel board 300 is coupled to the first cover 100, the display element 322 is aligned with the second opening 122 of the first cover 100, as shown in FIG. 3. The user may check whether the display element 322 is lit via a display (522 of FIG. 6) of the operation panel 500 described below and the second opening 122 connected to the display part 522. The display element 323 may be a display element such as a seven segment display element, for example. Although not shown, when the operation panel board 300 is coupled to the first cover 100, the display element 323 is aligned with the second opening 123 of the first cover 100. The user may check information displayed on the display element 323 via a display (523 of FIG. 6) of the operation panel 500 as described below and the second opening 123 connected to the display 523.

The electronic component may include a plurality of manipulation elements 321, and a plurality of first openings 121 corresponding to the plurality of manipulation elements 321 may be defined in the first front portion 101 of the first cover 100. The electronic component may include a plurality of display elements 322, and a plurality of second openings 122 corresponding to the plurality of display elements 322 may be defined in the first front portion 101 of the first cover 100. Although not illustrated in the drawings, the electronic component may include a plurality of display elements 323, and a plurality of second openings 123 corresponding to the plurality of display elements 323 may be defined in the first front portion 101 of the first cover 100.

The second cover 200 is disposed on an opposite side of the first front portion 101 of the first cover 100 relative to the operation panel board 300. The second cover 200 faces the first front portion 101 and is coupled to the first cover 100 to face the first front portion 101, thereby closing the first accommodation space 390. The second cover 200, together with the first front portion 101 and the first side portion 102 of the first cover 100, forms the closed first accommodation space 390 in which the operation panel board 300 is accommodated. In an embodiment, the second cover 200 may include a second front portion 201 facing the first front portion 101 of the first cover 100 and closing the first accommodation space 390, for example. The first front portion 101 of the first cover 100 and the second front portion 201 of the second cover 200 face each other in the thickness direction. With this configuration, the closed first accommodation space 390 may be defined by the first front portion 101 of the first cover 100, the second front portion 201 of the second cover 200, and the first side portion 102 of the first cover 100. In an embodiment, the second cover 200 may be coupled to the first cover 100 by various coupling methods such as snap-fit coupling, screw coupling, etc., for example. The second cover 200 may be coupled to ends of the first side portion 102 of the first cover 100. Although not illustrated in the drawings, the second cover 200 may include an extension portion extending from an edge of the second front portion 201 toward the first side portion 102 of the first cover 100, and the first side portion 102 of the first cover 100 and the extension portion may be engaged with each other. According to this configuration, the closed first accommodation space 390 may be defined by the first front portion 101 of the first cover 100, the second front portion 201 of the second cover 200, the first side portion 102 of the first cover 100, and the extension portion of the second cover 200.

A conventional first cover has a structure in which a front portion is open and a rear portion is closed. An operation panel board is arranged inside the first cover so that its component surface faces the open front portion. The first cover is coupled to an operation panel so that the component surface of the operation panel board faces a rear portion of an operation panel, i.e., the open front portion of the first cover faces the rear portion of the operation panel. In this structure, because the front portion of the first cover is completely open, during handling of a board assembly in which the first cover is coupled to the operation panel board, the component surface of the operation panel board may be directly exposed to moisture via the open front surface of the first cover. Furthermore, with the board assembly coupled to the operation panel, there is a relatively high probability of permeation of moisture into the operation panel board through the operation panel. In order to protect the component surface of the operation panel board from moisture, after the operation panel board is assembled to the first cover, a process is desired in which a waterproof molding layer is formed by injecting a waterproof molding liquid, such as a polyurethane molding liquid, into the first cover so that the component surface of the operation panel board is completely coated, and then curing the waterproof molding liquid. For this process, equipment for heating and mixing polyurethane base resin and curing agent, drying equipment for curing, and personnel who operate the equipment are desired. Therefore, the manufacturing cost of the operation panel assembly may be relatively high due to equipment and labor costs.

As described above, in the operation panel assembly in the illustrated embodiment, the first cover 100 is shaped to include the entirely open rear portion that is on the opposite side of the first front portion 101, and the operation panel board 300 is coupled to the first cover 100 such that the first surface 301, i.e., a component surface on which the electronic component is disposed (e.g., mounted), faces the first front portion 101. The second cover 200 closes the open rear portion of the first cover 100. The second cover 200 is coupled to the first cover 100 to close the first accommodation space 390 in which the operation panel board 300 is received. Therefore, a board assembly 10 including the first cover 100, the operation panel board 300, and the second cover 200 is implemented. The first accommodation space 390 in which the operation panel board 300 is received is substantially closed by the first cover 100 and the second cover 200. In addition, because the component surface of the operation panel board 300, i.e., the first surface 301, is covered by the first front portion 101 of the first cover 100, the component surface of the operation panel board 300 may be effectively protected from moisture compared to a conventional structure in which the front portion of the first cover is completely open. Therefore, the conventional process of forming the polyurethane waterproof molding layer may be omitted, and the manufacturing cost of the operation panel assembly may be reduced.

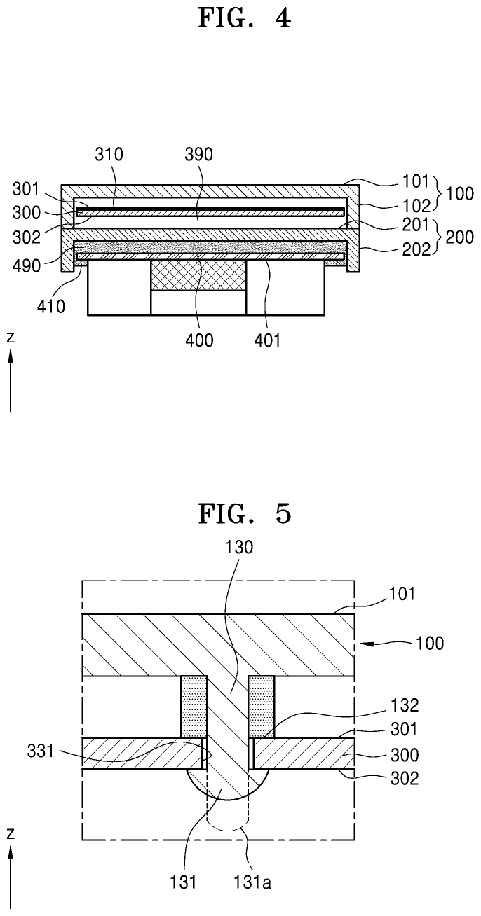

FIG. 4 is a cross-sectional view of an embodiment of an operation panel assembly for an electric appliance, according to the disclosure. In FIG. 4, the openings of the first cover 100 and the electronic components on the operation panel board 300 are omitted and are not shown. Referring to FIG. 4, an operation panel assembly of the illustrated embodiment is different from the operation panel assembly of the embodiment shown in FIGS. 1 to 3 in that a waterproof coating layer 310 is formed on the component surface, i.e., the first surface 301, of the operation panel board 300. Therefore, the difference is mainly described, and descriptions already provided above are omitted. The waterproof coating layer 310 may include a conformal coating layer formed by spraying or applying an organic solvent coating agent to the first surface 301 of the operation panel board 300. A thickness of the conformal waterproof coating layer 310 may range from several tens to several hundreds of micrometers, for example. The organic solvent coating agent may be a toluene-based coating agent such as Dow Corning LDC 2577, for example.

Unlike a molding layer that covers the entirety of the board, the conformal waterproof coating layer is formed only on a surface of the board, so the desired amount of the coating agent is about one tenth ( 1/10) of the amount of the molding agent. Unlike the molding layer that desires heating and drying, the conformal waterproof coating layer may be dried naturally. While about 40 minutes of drying time is desired for the molding layer, about 10 minutes of drying time is desired for the conformal waterproof coating layer. In order to form the molding layer, a plurality of holes through which the molding agent passes need to be defined in the operation panel board 300, and a horizontal design of the first cover 100 is desired to uniformly form the molding layer. Furthermore, there is a possibility that the switch element or the display element may be contaminated by the molding layer or locked in the molding layer to cause it to malfunction. Because the conformal waterproof coating layer is formed using an application process, there is no need for a horizontal design of the first cover 100, and there is a relatively low possibility of contamination of the switch element or display element due to the coating layer.

Referring to FIGS. 2 and 4, the second cover 200 may include the second front portion 201 facing the first front portion 101 of the first cover 100 and a second side portion 202 extending from the second front portion 201 to an opposite side of the first cover 100. The second cover 200 may be shaped to define an open rear space that is the opposite side of the second front portion 201. A second accommodation space 490 may be defined by the second front portion 201 and the second side portion 202 of the second cover 200. A main board 400 is arranged in the second accommodation space 490. The main board 400 may include electrical/electronic components for driving and controlling the electric appliance. The operation panel board 300 may be connected to the main board 400 by a connection means (not shown) such as a cable or the like. The main board 400 is arranged so that the component surface 401 faces the opposite side of the second front portion 201, i.e., the open rear portion. In order to protect the main board 400 from moisture, a waterproof molding layer 410 may be provided to cover the component surface of the main board 400. The waterproof molding layer 410 may fill the second accommodation space 490, for example. The waterproof molding layer 410 may be a polyurethane molding layer, for example. The component surface 401 of the main board 400 is buried in the waterproof molding layer 410. According to this configuration, because the second cover 200 that closes the first accommodation space 390 in which the operation panel board 300 is accommodated may double as an installation member for the main board 400, the manufacturing costs of the operation panel assembly and the electric appliance may be reduced.

A manipulation force is exerted on the manipulation element 321 by the user. The manipulation force may be a force exerted when pressing the manipulation element 321, for example. The operation panel board 300 needs to be evenly coupled to the first cover 100. When the operation panel board 300 is bent downward, a distance between the manipulation element 321 and the first front portion 101 of the first cover 100 increases, so that the user's manipulation force may not be transmitted to the manipulation element 321 or may be unstably transmitted thereto. In addition, the operation panel board 300 may be bent downward due to a user's manipulation force applied to the manipulation element 321. Even in this case, the user's manipulation force may not be transmitted to the manipulation element 321 or may be unstably transmitted thereto. Considering this point, a structure for preventing bending of the operation panel board 300 may be applied to the operation panel assembly.

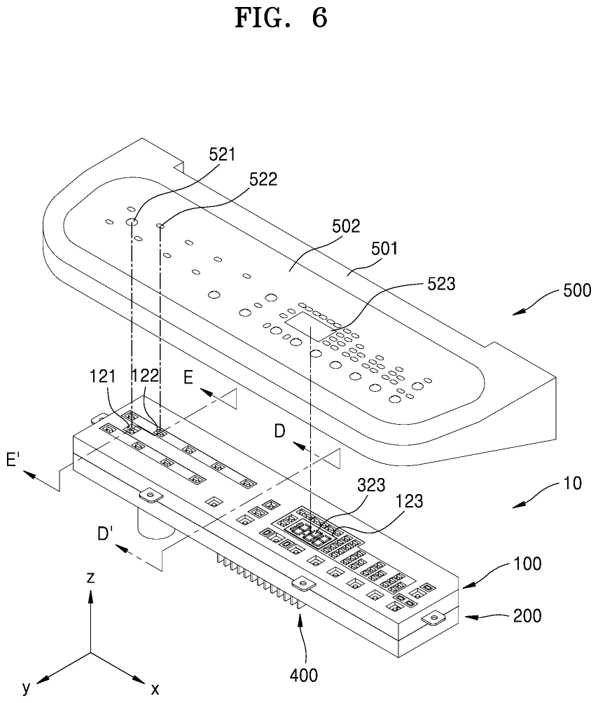

FIG. 5 is a cross-sectional view of the operation panel assembly taken along line C-C′ of FIG. 1. Referring to FIGS. 1 and 5, a through-hole 331 is defined in the operation panel board 300. The through-hole 331 is formed to penetrate the operation panel board 300 in the thickness direction. The through-hole 331 may be disposed adjacent to the manipulation element 321. The first cover 100 is provided with a fusion protrusion 130. The fusion protrusion 130 protrudes from the first front portion 101 of the first cover 100 toward the rear portion. When the operation panel board 300 is coupled to the first cover 100, the fusion protrusion 130 is inserted into the through-hole 331, and protrudes outward from a second surface 302 of the operation panel board 300. In an embodiment, the first cover 100 may include a support portion 132 on which the first surface 301 of the operation panel board 300 is supported, for example. The support portion 132 may have a rib shape, e.g., that protrudes from the first front portion 101 toward the rear portion. A length from the support portion 132 to the end 131a of the fusion protrusion 130 is greater than the thickness of the operation panel board 300. Therefore, when the operation panel board 300 is coupled to the first cover 100, the end 131a of the fusion protrusion 130 protrudes outward from the second surface 302 of the operation panel board 300. In this state, the protruding end 131a is fused to the second surface 302 of the operation panel board 300. The fusion may be performed, e.g., by an ultrasonic fusion process, a thermal fusion process, or the like.

According to this configuration, a fusion head 131 is formed on the second surface 302 of the operation panel board 300. A diameter of the fusion head 131 is greater than a diameter of the through-hole 331. Because the second surface 302 of the operation panel board 300 is supported by the fusion head 131, backward bending of the operation panel board 300 may be prevented when the operation panel board 300 is coupled to the first cover 100. In addition, backward bending of the operation panel board 300 due to a manipulation force applied to the manipulation element 321 may be prevented.

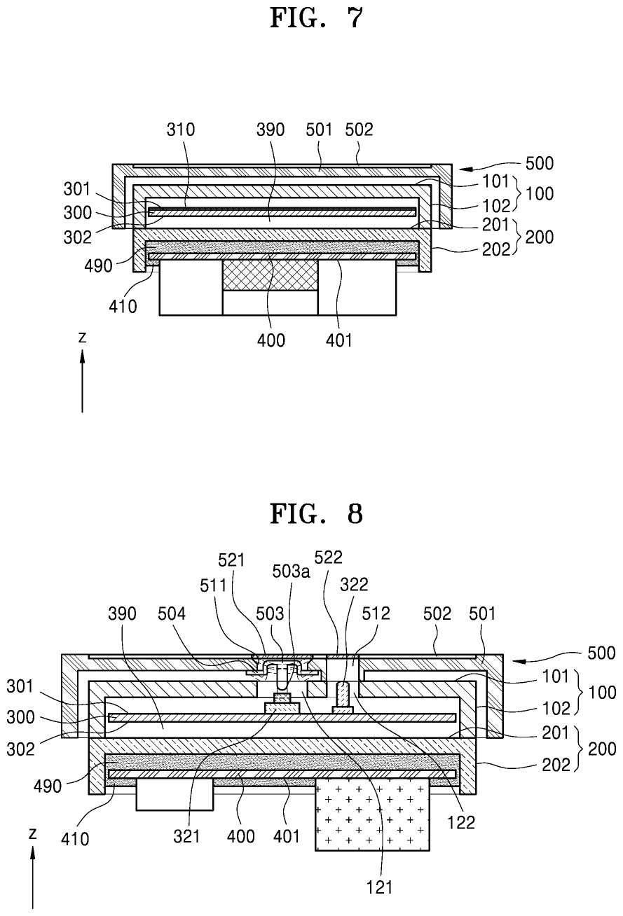

FIG. 6 is an exploded perspective view of an embodiment of an operation panel assembly for an electric appliance, according to the disclosure. FIG. 7 is a schematic cross-sectional view of an embodiment of the operation panel assembly for the electronic appliance, taken along line D-D of FIG. 6, according to the disclosure. In FIG. 7, the openings of the first cover 100 and the electronic components on the operation panel board 300 are omitted and are not shown. FIG. 8 is a schematic cross-sectional view of an embodiment of the operation panel assembly for the electronic appliance, taken along line E-E′ of FIG. 6, according to the disclosure.

Referring to FIGS. 6 to 8, the operation panel assembly may include an operation panel 500. The operation panel 500 is disposed opposite to the first front portion 101 of the first cover 100 to access the electronic components disposed (e.g., mounted) on the first surface 301 of the operation panel board 300 through the openings 121, 122, and 123 of the first cover 100. In an embodiment, the board assembly 10 may be coupled to the operation panel 500, for example. Because the board assembly 10 is the same as described in FIGS. 1 to 5, descriptions already provided above are omitted. The operation panel 500 forms an outermost part of the operation panel assembly. The operation panel 500 may include a frame 501 and a display manipulation unit 502. The board assembly may be coupled to the inside of the frame 501 by a screw fastening method or the like. In an embodiment, the display manipulation unit 502 may be implemented by a film attached to an outer surface of the frame 501, for example. The display manipulation unit 502 may include a manipulation part 521 that receives a user's manipulation input and display parts 522 and 523 that allow the user to visually recognize an operation state of the electric appliance. The manipulation part 521 is a part that is pressed or touched by a user, and may be printed in a predetermined shape on a surface of the display manipulation unit 502 so that the manipulation part 521 may be visually recognized. The manipulation part 521 may also have a convexly protruding shape. The display parts 522 and 523 are parts through which light may pass. In an embodiment, the display parts 522 and 523 may be dimmed to scatter light, for example. Characters or designs indicating functions of the manipulation part 521 and the display parts 522 and 523 may be printed on the display manipulation unit 502.

Referring to FIG. 8, the frame 501 defines a third opening 511. The third opening 511 is aligned with the first opening 121 defined in the first front portion 101 of the first cover 100. A button 503 may be defined in the third opening 511. The button 503 may be connected to a frame 501 by a resilient arm 504, for example. The manipulation part 521 may contact the button 503. When a manipulation force is applied to the manipulation part 521, the resilient arm 504 is elastically deformed to press the button 503 toward the operation panel board 300, as indicated by a dashed line in FIG. 8. Then, a pressing part 503a of the button 503 may press the manipulation element 321 disposed (e.g., mounted) on the operation panel board 300 to operate the manipulation element 321. A manipulation signal from the manipulation element 321 may be transmitted to the main board 400 via a cable (not shown), and the main board 400 may control the electric appliance to perform an operation corresponding to the manipulation signal. When the manipulation force applied to the manipulation part 521 is released, the button 503 may be returned to a position as indicated by a solid line in FIG. 8 by an elastic restoring force from the resilient arm 504.

Referring back to FIG. 8, the frame 501 defines a fourth opening 512. The fourth opening 512 is aligned with the second opening 122 defined in the first front portion 101 of the first cover 100. The display part 522 covers the fourth opening 512. When the display element 322 is lit, light passes through the second opening 122 and the fourth opening 512, and the user may recognize whether the display element 322 is lit via the display part 522, and check an operation state of the electric appliance.

Although not illustrated in the drawings, the frame 501 may define a fifth opening aligned with the second opening 123 defined in the first cover 100. The display part 523 covers the fifth opening. Visual information displayed on the display element 323, e.g., a seven segment display element, is projected onto the display part 523 through the second opening 123 and the fifth opening, and the user may view the information displayed on the display element 323 via the display part 523.

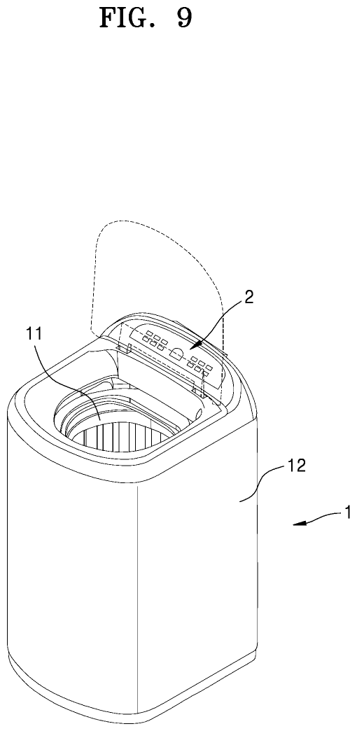

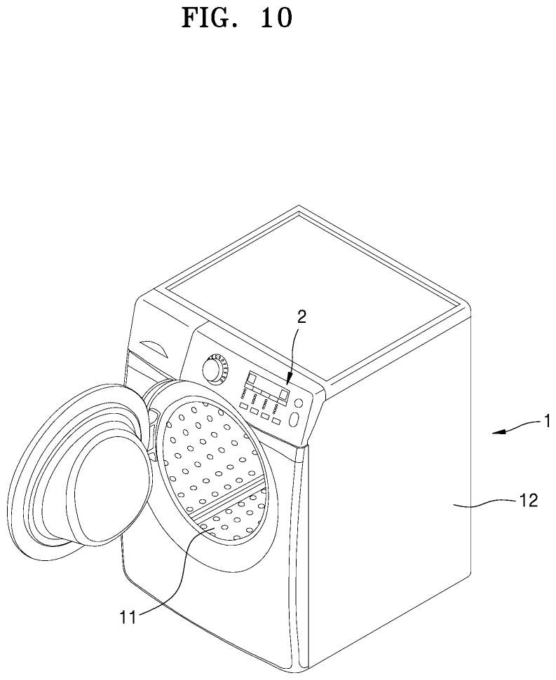

FIGS. 9 and 10 are schematic perspective views of an embodiment of electric appliances according to the disclosure. The electric appliance of FIG. 9 is a top-loading washing machine. The electric appliance of FIG. 10 is a drum-type washing machine. Referring to FIGS. 9 and 10, the washing machine may include a body 1 and an operation panel assembly 2 for at least one of manipulation input and display of a state of the body 1.

The body 1 may include components for performing functions of the washing machine. In an embodiment, the body 1 may include a washing tub 11 in which laundry is received, for example. The washing tub 11 may be accommodated inside a housing 12 forming the exterior of the body 1. Although not illustrated in the drawings, the body 1 may include a water supply and drainage structure for supplying water to and draining water from the washing tub 11, a driving structure for rotating the washing tub 11 or water and laundry inside the washing tub 11, etc. The operation panel assembly 2 may be the same as illustrated in FIGS. 1 to 8. The operation panel assembly 2 may be coupled to the body 1. The operation panel 500 may form the exterior of the washing machine together with the housing 12. A manipulation input received via the manipulation part 521 of the operation panel 500 may be transmitted to the main board 400 through the operation panel board 300 in the form of a manipulation signal. The main board 400 may drive and control the body 1 according to the manipulation signal. A manipulation status of the body 1 may be displayed via the display parts 522 and 523 of the operation panel 500.

Although not shown, the electric appliance may be a dryer. The body 1 may include a drying container for receiving an object to be dried, such as laundry, a heat supply structure for supplying hot air to the inside of the drying container, a driving structure for rotating the drying container as desired, etc. The electric appliance may be a dehydrator. The body 1 may include a dehydration tub, a drainage structure for discharging water from the dehydration tub, a driving structure for rotating the dehydration tub, etc. The body 1 may also be a dishwasher.

While embodiments have been particularly described above, it will be understood that the scope of the disclosure is not limited thereto and various modifications and improvements made by one of ordinary skill in the art based on a basic concept of the disclosure also fall within the scope as defined by the following claims.

1. A washing machine comprising:
a body including a washing tub; and
an operation panel assembly which receives a manipulation input or displays an operation state of the body, the operation panel assembly comprising:
a first cover including:
a first front portion defining an opening; and
a first side portion extending from the first front portion, the first front portion and the first side portion defining a first accommodation space;
an operation panel board including:
a first surface on which an electronic component aligned with the opening of the first cover is disposed; and
a second surface opposite to the first surface and arranged in the first accommodation space so that the first surface faces the first front portion; and
a second cover which is coupled to the first cover and closes the first accommodation space.

2. The washing machine of claim 1, comprising a waterproof coating layer formed on the first surface of the operation panel board.

3. The washing machine of claim 2, wherein the waterproof coating layer includes a conformal coating layer.

4. The washing machine of claim 1, comprising:
a through-hole which penetrates the operation panel board; and
a fusion protrusion extending from the first front portion, passing through the through-hole, protruding outward from the second surface of the operation panel board, and including a protruding end fused to the second surface.

5. The washing machine of claim 1, wherein the second cover includes a second front portion facing the first front portion of the first cover and a second side portion extending from the second front portion to an opposite side of the first cover, wherein an opposite side of the second front portion is open.

6. The washing machine of claim 5, comprising a main board arranged in a second accommodation space formed by the second front portion and the second side portion.

7. The washing machine of claim 6, wherein the main board is accommodated in the second accommodation space so that a component surface faces an opposite side of the second front portion.

8. The washing machine of claim 7, comprising a waterproof molding layer filling the second accommodation space and covering the component surface of the main board.

9. The washing machine of claim 1, comprising an operation panel disposed opposite to the first front portion of the first cover so that the electronic component is accessed through the opening.

10. An operation panel assembly for an electric appliance, the operation panel assembly comprising:
a first cover including a first front portion defining an opening and a first side portion extending from the first front portion, the first front portion and the first side portion defining a first accommodation space;
an operation panel board including:
a first surface on which an electronic component aligned with the opening of the first cover is disposed; and
a second surface opposite to the first surface, and arranged in the first accommodation space so that the first surface faces the first front portion; and
a second cover which is coupled to the first cover and closes the first accommodation space.

11. The operation panel assembly of claim 10, comprising a conformal waterproof coating layer formed on the first surface of the operation panel board.

12. The operation panel assembly of claim 10, comprising:
a through-hole which penetrates the operation panel board; and
a fusion protrusion extending from the first front portion, passing through the through-hole, protruding outward from the second surface of the operation panel board, and including a protruding end fused to the second surface.

13. The operation panel assembly of claim 10, wherein
the second cover includes a second front portion facing the first front portion of the first cover and a second side portion extending from the second front portion to an opposite side of the first cover, wherein an opposite side of the second front portion is open, and
the operation panel assembly comprises a main board arranged in a second accommodation space formed by the second front portion and the second side portion so that a component surface faces an opposite side of the second front portion.

14. The operation panel assembly of claim 13, comprising a waterproof molding layer filling the second accommodation space and covering the component surface of the main board.

15. The operation panel assembly of claim 10, comprising an operation panel disposed opposite to the first front portion of the first cover so that the electronic component is accessed through the opening.
